(19) United States
(12) Patent Application Publication
(10) Pub. No.: US 2025/0211196 A1
(43) Pub. Date: Jun. 26, 2025

(54) PIEZOELECTRIC WAFER AND METHOD OF FABRICATING THE SAME AND ACOUSTIC WAVE DEVICE INCLUDING THE SAME

(71) Applicant: QUANZHOU SANAN INTEGRATED CIRCUIT CO., LTD., Quanzhou City (CN)

(72) Inventors: Minghui FANG, Quanzhou City (CN); Zhonghe LIN, Quanzhou City (CN); Minghua SU, Quanzhou City (CN); Shihwei HUANG, Quanzhou City (CN); Shengyu YANG, Quanzhou City (CN); Yilin LIU, Quanzhou City (CN)

(21) Appl. No.: 18/902,318

(22) Filed: Sep. 30, 2024

(30) Foreign Application Priority Data
Dec. 20, 2023 (CN) 202311765188.4

(51) Int. Cl. H03H 9/02; H03H 3/08

(52) U.S. Cl. CPC H03H 9/02559; H03H 3/08

(57) ABSTRACT

A piezoelectric wafer comprises a center region and an edge region. The piezoelectric wafer has a color difference (ΔE) of no greater than 3. The color difference (ΔE) is expressed by

ΔE=\sqrt{(Lₘₐₓ−Lₘᵢₓ)²} where the color difference (ΔE) is obtained from multiple chromaticity values (L) measured at several evenly distribution areas selected from a central region and an edge region of the piezoelectric wafer, (Lₘₐₓ) is a maximum value of the chromaticity values (L), and (Lₘᵢₙ) is a minimum value of the chromaticity values (L). A method of fabricating the described piezoelectric wafer, and an acoustic wave device includes the described piezoelectric wafer.

### CROSS-REFERENCE TO RELATED APPLICATION

This application claims priority to Chinese Invention Patent Application No. 202311765188.4, filed on Dec. 20, 2023, and incorporated by reference herein in its entirety.

### FIELD

The disclosure relates to a device, and more particularly to a piezoelectric wafer, a method of fabricating the piezoelectric wafer, and an acoustic wave device including the piezoelectric wafer.

### BACKGROUND

Lithium Tantalate (LT) crystals are mainly used as a Surface Acoustic Wave (SAW) filter material for high-frequency signal processing of mobile phones. However, an LT substrate (made from LT crystals) presents two main problems in SAW filter device fabrication. Firstly, since the LT substrate has high light transmittance, light may be reflected at the back surface of the substrate and returned to the surface during a photolithography process, which is one of the manufacturing processes of making the SAW filter device. This will result in a problem of resolution reduction of a formed pattern. Secondly, because LT crystals have a high pyroelectric coefficient, a chip fabricated from LT crystals may have a problem where a large static charge is easily accumulated on the surface of the chip under the influence of temperature variation, and the static charge can be spontaneously released between metal interdigital electrodes or between the chips. This may cause problems such as chip cracking or metal interdigital electrode burning and the like.

Therefore, in order to solve the above problems, the LT substrate is subjected to a reduction treatment to reduce the resistivity thereof, and the LT substrate is changed from white or pale yellow to gray or black during the reduction treatment. Therefore the reduction treatment is also known as “blackening”. Blackening the LT substrate effectively solves the problem of high light transmittance causing resolution reduction in the formed pattern. Additionally, the blackening reduction treatment also improves conductivity which reduces the pyroelectric effect, and the problems of chip cracking or metal interdigital electrode burning caused by electrostatic discharge can be avoided. However, the conventional lithium tantalate wafer has poor blackening effect, obvious black spots are easily formed at the edge of the substrate, and the blackened wafer is too dark or too light in shade, so that the lithium tantalate wafer is less suitable for photolithography, and electrodes will be difficult to fabricate on the tantalate wafer when manufacturing the electrodes later.

### SUMMARY

Therefore, an object of the disclosure is to provide a piezoelectric wafer, a method of fabricating the same, and an acoustic wave device including the same that can alleviate at least one of the drawbacks of the prior art.

According to one aspect of the disclosure, a piezoelectric wafer includes a center region and an edge region. The piezoelectric wafer has a color difference (ΔE) of no greater than 3. The color difference (ΔE) is expressed by ΔE=\sqrt{(Lₘₐₓ−Lₘᵢₓ)²} where the color difference (ΔE) is obtained from multiple chromaticity values (L) measured at several evenly distributed areas selected from a central region and an edge region of the piezoelectric wafer, (Lₘₐₓ) is a maximum value of the chromaticity values (L), and (Lₘᵢₙ) is a minimum value of the chromaticity values (L).

According to another aspect of the disclosure a method of fabricating a piezoelectric wafer described above includes processing a piezoelectric wafer so that a color difference (ΔE) of the piezoelectric wafer is no greater than 3. The color difference (ΔE) is expressed by ΔE=\sqrt{(Lₘₐₓ−Lₘᵢₓ)²} where the color difference (ΔE) is obtained from multiple chromaticity values (L) measured at several evenly distributed points selected from a central region and an edge region of the piezoelectric wafer, (Lmax) is a maximum value of the chromaticity values (L), and (Lmin) is a minimum value of the chromaticity values (L).

According to yet another aspect of the disclosure an acoustic wave device includes the piezoelectric wafer in the another aspect.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a first embodiment of the present disclosure which includes a method of fabricating a piezoelectric wafer.

FIG. 2 is an image of a conventional piezoelectric wafer made according to a conventional method.

FIG. 3 is an image of a piezoelectric wafer made according to the method of the first embodiment.

FIG. 4 is a chromaticity over time plot obtained after UV exposure of a piezoelectric wafer treated with a conventional reducing agent.

FIG. 5 is a chromaticity over time plot obtained after UV exposure of a piezoelectric wafer treated with a reducing agent according to the present disclosure.

FIG. 6 is a chromaticity over wavelength plot of the piezoelectric wafer treated with the conventional reducing agent and obtained after a thinning process.

FIG. 7 is a chromaticity over wavelength plot of the piezoelectric wafer treated with the reducing agent according to the present disclosure and obtained after a thinning process.

FIG. 8 is a color difference over reducing agent fineness plot.

FIG. 9 is a block diagram illustrating a method of fabricating the piezoelectric wafer according to a second embodiment of the disclosure.

FIG. 10 is a chromaticity over time plot obtained after UV exposure for comparing a comparative sample to an exemplary sample made by the first embodiment.

FIG. 11 is light transmittance over wavelength plot comparing a light transmittance of a central region to a light transmittance of an edge region of an exemplary sample made by the first embodiment.

FIG. 12 is a light transmittance over wavelength plot comparing a light transmittance of a central region to a light transmittance of an edge region of a conventional piezoelectric wafer.

FIG. 13 is another image of a piezoelectric wafer made by the first embodiment.

FIG. 14 is still another image of a piezoelectric wafer made by the first embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

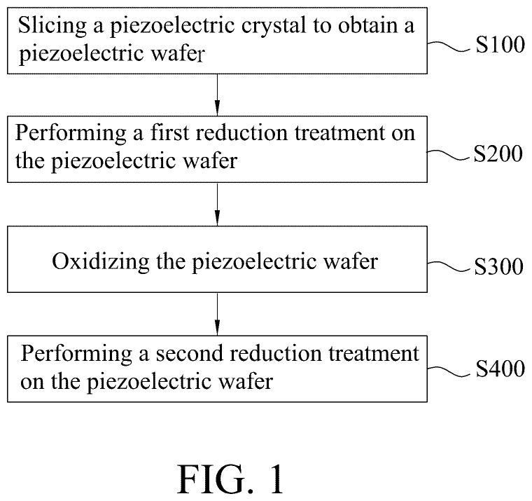

Referring to FIG. 1, a first embodiment of the present disclosure is a method of fabricating a piezoelectric wafer. The method includes steps (S100) to (S400). In the step (S100), a piezoelectric crystal is sliced to obtain a piezoelectric wafer. In the step (S200), a first reduction treatment is performed on the piezoelectric wafer. In the step (S300), the piezoelectric wafer is oxidized after the first reduction treatment. In the step (S400), a second reduction treatment is performed on the piezoelectric wafer after the oxidizing of the piezoelectric wafer so that a color difference (ΔE) of the piezoelectric wafer is no greater than 3. The color difference (ΔE) is expressed by,

$$Δ E = \sqrt{{( {L}_{max} - {L}_{mix} )}^{2}}$$

where the color difference (ΔE) is obtained from multiple chromaticity values (L) measured at several evenly distributed points selected from a central region and an edge region of the piezoelectric wafer, (Lₘₐₓ) is a maximum value of the chromaticity values (L), and (Lₘᵢₙ) is a minimum value of the chromaticity values (L).

In some embodiments, the piezoelectric crystal is made of lithium tantalate. In other embodiments, the piezoelectric crystal is made of lithium niobate. It should be noted that there is no limitation on the thickness of the piezoelectric wafer obtained from slicing the piezoelectric crystal. The thickness of the piezoelectric wafer may be determined according to practical requirements.

In some embodiments, the first reduction treatment and the second reduction treatment may be performed on a “blackening” jig. It should be noted that the specific structure of the blackening jig is not limited in this disclosure.

After the piezoelectric wafer is subjected to the first reduction treatment is the step (S200), oxygen vacancies in the piezoelectric wafer form a concentration gradient, and cannot reach an optimal equilibrium state. However, after the piezoelectric wafer is subjected to oxidation in step (S300) and the second reduction treatment in step (S400), the distribution of oxygen vacancies can become uniform and the piezoelectric wafer can reach an optimal equilibrium state which is not prone to destruction by external energy.

The way of performing the oxidization of the piezoelectric wafer in step (S300) and the way of performing the second reduction treatment in step (S400) are not limited according to the disclosure. There are several known methods for oxidizing and reducing piezoelectric wafers in the art. Any one of these known methods may be used for oxidizing and reducing the piezoelectric wafer which has been subjected to the first reduction treatment of step (S200). It should be noted that the second reduction treatment may use the same method as the first reduction treatment.

In this disclosure, after the piezoelectric wafer is subjected to the first reduction treatment, the oxidizing treatment, and the second reduction treatment, the color difference (ΔE) of the piezoelectric wafer is no greater than 3. It should be noted that the color difference (ΔE) expresses the color uniformity within the piezoelectric wafer, and the smaller the value, the better the uniformity. More specifically, (ΔE) is expressed by,

$$Δ E = \sqrt{{( {L}_{max} - {L}_{mix} )}^{2}}$$

where the color difference (ΔE) is obtained from multiple chromaticity values (L) measured at several evenly distributed points selected from a central region and an edge region of the piezoelectric wafer. It should be noted that the chromaticity value (L) expresses the shade of the color, a higher chromaticity value (L) represents a lighter shade, and a lower chromaticity value represents a darker shade. (Lₘₐₓ) is a maximum value of the chromaticity values (L), and (Lₘᵢₙ) is a minimum value of the chromaticity values (L).

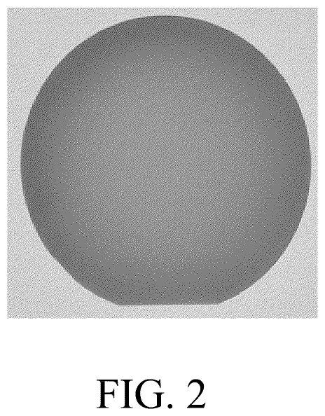

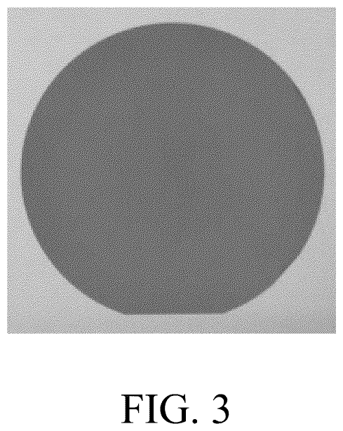

FIG. 2 shows a conventional piezoelectric wafer made according to a conventional method. FIG. 3 is a piezoelectric wafer made according to the first embodiment of the disclosure. From comparing FIG. 2 to FIG. 3, it may be observed that the piezoelectric wafer according to the present disclosure has a color difference (ΔE) that is no greater than 3, and has a better color uniformity when compared to the conventional piezoelectric wafer.

In some embodiments, the color difference (ΔE) of the piezoelectric wafer may be no greater than 1. In general the color difference (ΔE) of the piezoelectric wafer should be made as small as possible.

In summary of the above, the method of fabricating the piezoelectric wafer includes performing the first reduction treatment, oxidizing the piezoelectric wafer, and performing the second reduction treatment on the piezoelectric wafer. In this way, the color difference (ΔE) of the piezoelectric wafer may be made to be no greater than 3 which improves color uniformity between the central region and the edge region of the piezoelectric wafer. Therefore, the “blackening” of the piezoelectric wafer is improved. This prevents the problem of making the piezoelectric wafer unsuitable for photolithography, which negatively effects the fabrication of electrodes in a later process.

In some embodiments, a reducing agent for performing the first reduction treatment on the piezoelectric wafer is a carbonate.

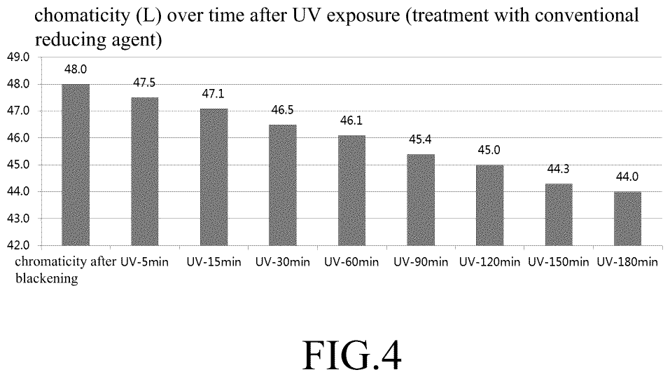

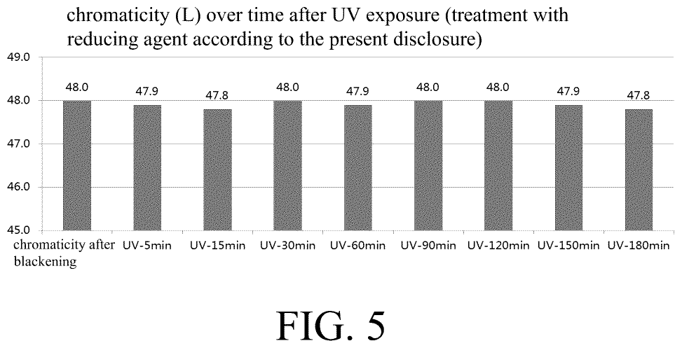

FIGS. 4 and 5, each show a piezoelectric wafer treated with different reducing agents for the first reduction treatment. FIG. 4 shows a piezoelectric wafer treated with a conventional reducing agent, while FIG. 5 shows a piezoelectric wafer treated with the carbonate reducing agent according to the disclosure. In some embodiments, the piezoelectric wafer may be treated with a carbonate powder or a carbonate powder mixture. For example, the piezoelectric wafer may be treated with lithium carbonate, sodium carbonate, magnesium carbonate, a combination, or combinations of the above. In this embodiment, the piezoelectric wafer is treated with lithium carbonate. From comparing FIGS. 4 and 5, it is apparent that the piezoelectric wafer treated with the reducing agent (lithium carbonate) according to the present disclosure (FIG. 4) basically does not change color after exposure to UV light. While, on the other hand, the piezoelectric wafer treated with the conventional reducing agent (FIG. 5) changes color by growing darker in color with prolonged exposure to UV light.

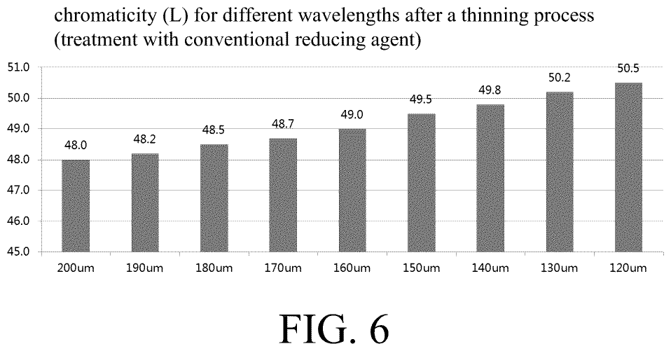

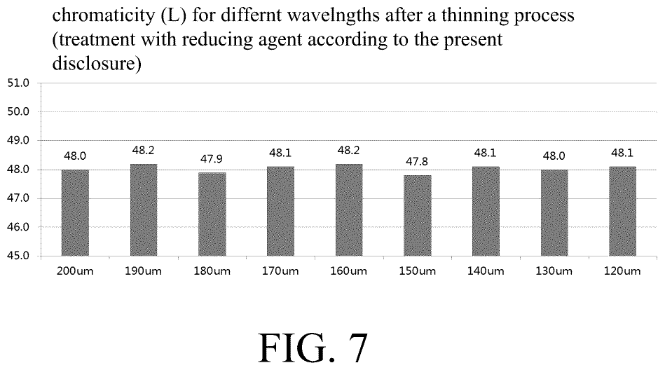

After the piezoelectric wafers are respectively treated with the conventional reducing agent and the reducing agent of the present disclosure, the piezoelectric wafers are subjected to a thinning process. FIG. 6 and FIG. 7 respectively show a color change of the piezoelectric wafer treated with the conventional reducing agent and subjected to the thinning process, and a color change of the piezoelectric wafer treated with the reducing agent according to the present disclosure and subjected to the thinning process. By comparing FIG. 6 with FIG. 7, it is apparent that the piezoelectric wafer treated with the reducing agent according to the present disclosure does not change color after thinning, while the piezoelectric wafer treated with the conventional reducing agent becomes lighter in shade as the piezoelectric wafer is thinned. Therefore, it is clear that using carbonate as the reducing agent provides better color stability and better color uniformity.

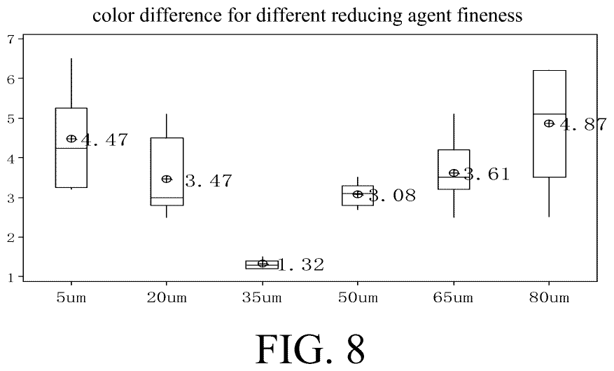

FIG. 8 shows a relationship between color uniformity (where a smaller (ΔE) equates to better uniformity) and fineness of the reducing agent. From FIG. 8 it may be observed that uniformity gradually improves with increasing fineness (i.e., decreasing particle sizes) of the reducing agent, but after a particular fineness level is reached, uniformity deteriorates as the particle size of the reducing agent increases. Therefore, in this embodiment, the reducing agent used for the first reduction treatment is a powder with a fineness (particle size) that ranges from 25 μm to 45 μm. In some embodiments, the reducing agent is a powder with a fineness that ranges from 30 μm to 40 μm.

It is noted from FIG. 8 that when the reducing agent has a fineness of 35 μm, the color difference (ΔE) is 1.32, and the piezoelectric wafer has the best uniformity.

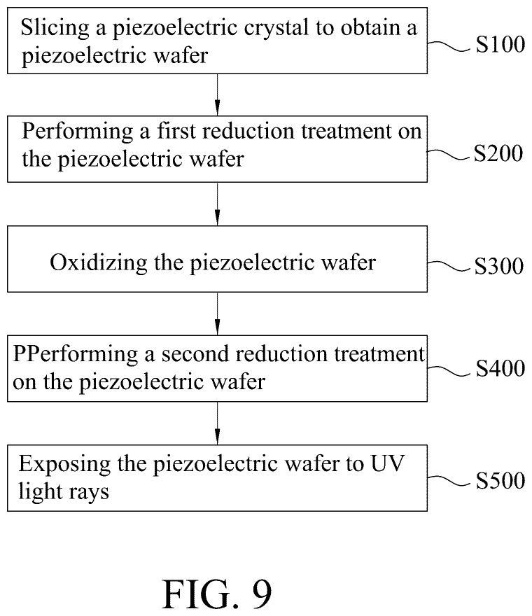

Referring to FIG. 9, a second embodiment of the disclosure is also a method, but differs from the first embodiment in that after the second reduction treatment is performed on the piezoelectric wafer in the step (S400), the piezoelectric wafer is exposed to UV light rays in a step (S500).

It should be noted that by exposing the piezoelectric wafers to UV light rays, because the electron carriers in the piezoelectric wafer are mainly oxygen vacancies, the oxygen vacancies are excited to a conduction band or valence band by utilizing the photoconductive effect of ultraviolet light on the piezoelectric wafer, and because the oxygen vacancies are in a concentration gradient, the oxygen vacancies can move from a place with higher concentration to a place with lower concentration, so that the excited oxygen vacancies may be captured again, and a new balance may be achieved. Therefore, the concentration of the oxygen vacancies in the piezoelectric wafer may be uniformly distributed by exposing the piezoelectric wafer to UV light rays.

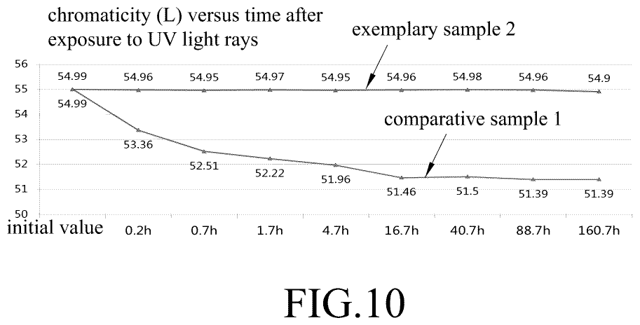

Referring to FIG. 9, a comparison between an exemplary sample produced by the second embodiment and a comparative sample produced by a conventional method is shown. The comparative sample was subjected to a first reduction treatment and exposure to UV light rays, but did not undergo oxidizing, or a second reduction treatment. The exemplary sample was subjected to the first reduction treatment, oxidization, a second reduction treatment, and UV light ray exposure. FIG. 10 compares the chromaticity values (L) of the comparative sample with that of the exemplary sample. It is apparent from FIG. 10 that the chromaticity value (L) of the comparative sample substantially does not change anymore after 16.7 h of UV light exposure. On the other hand, the chromaticity values (L) of the exemplary sample basically does not change at all after UV light ray exposure and the color difference (ΔE) after blackening is less than 1. The results in FIG. 10 show that the color uniformity and stability of the exemplary sample is improved over the comparative sample.

A piezoelectric wafer made according to the method of the first embodiment or the second embodiment has a color difference (ΔE) that is no less than 3, and the color difference (ΔE) is express by ΔE=\sqrt{(Lₘₐₓ−Lₘᵢₓ)²}, where the color difference (ΔE) is obtained from multiple chromaticity values (L) measured at several evenly distributed points selected from a central region and an edge region of the piezoelectric wafer, (Lₘₐₓ) is a maximum value of the chromaticity values (L), and (Lₘᵢₙ) is a minimum value of the chromaticity values (L).

Of course, the piezoelectric wafer may have a color difference (ΔE) that is no greater than 1. In fact, it would be preferable for the color difference (ΔE) of the piezoelectric wafer to be as small as possible. It should be noted that a piezoelectric wafer fabricated from the method of the first or second embodiment may have a color difference (ΔE) that is no greater than 1.

In some embodiments, a difference in light transmittance of a first spectrum between the central region and the edge region of the piezoelectric wafer is no greater than 10%, where the first spectrum has a wavelength that ranges from 265 nm to 365 nm. In this way, the difference in light transmittance between the central region and the edge region of the piezoelectric wafer may be improved. This will improve the color uniformity of the piezoelectric wafer and prevents the problem of the piezoelectric wafer being unsuitable for photolithography, which negatively effects the fabrication of electrodes in a later process.

The piezoelectric wafer includes the central region and the edge region, where the central region is surrounded by the edge region. It should be noted that there is no limitation on areas of the edge region and the central region. The areas of the central region and the edge region may be designed according to practical requirements.

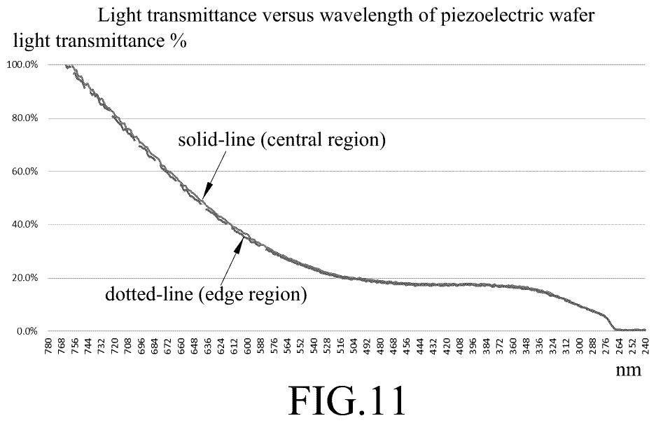

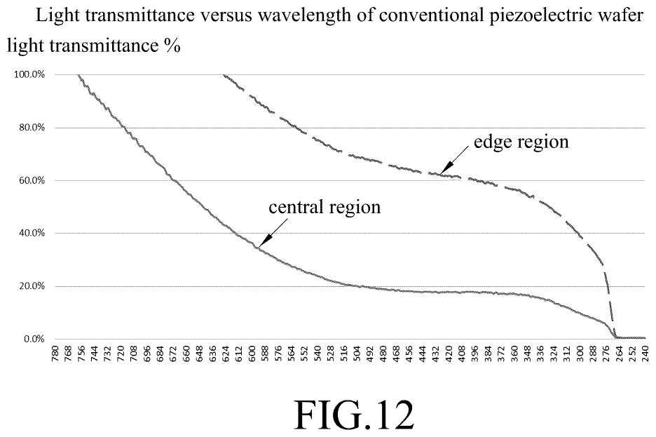

A piezoelectric wafer fabricated in the same way as the exemplary sample illustrated in FIG. 10, where a piezoelectric wafer is subjected to the first reduction treatment, oxidization, a second reduction treatment, and UV light ray exposure may have a difference in light transmittance of the first spectrum between the central region and the edge region of the piezoelectric wafer to be no greater than 10%. FIG. 11 shows the light transmittance of the central region (expressed by the solid line) and of the edge region (expressed by the dotted line) of the exemplary sample over wavelength. It may be observed from FIG. 11 that the piezoelectric wafer has a light transmittance in the first spectrum that is no greater than 20%. FIG. 12 shows the light transmittance of the central region (expressed by the solid line) and of the edge region (expressed by the dotted line) of a conventional piezoelectric wafer over wavelength.

For the first spectrum ranging from 265 nm to 365 nm, the difference in light transmittance between the central region and the edge region of the piezoelectric wafer is no greater than 10%. In this way the difference in light transmittance between different regions of the piezoelectric wafer is minimized which improves light transmittance uniformity and prevents the problem of the piezoelectric wafer being unsuitable for photolithography, which negatively effects the fabrication of electrodes in a later process.

Additionally, the piezoelectric wafer having a relatively high light transmittance will negatively affect accuracy during photolithography. When making a Surface Acoustic Wave (SAW) filter device, it is preferable for the piezoelectric wafer to have a light transmittance that is as low as possible in the ultraviolet spectrum. An electroplating process performed on the back of the piezoelectric wafer may be omitted if the piezoelectric wafer can be made completely opaque. In the case of the lithium tantalate piezoelectric wafer, if the difference in light transmittance between the central region and the edge region is too large, uneven results may be obtained when the lithium tantalate piezoelectric wafer undergoes photolithography which negatively effects the probability of obtaining electrodes that meet specifications in a later process. Therefore, in this embodiment, the difference in light transmittance of a first spectrum between the central region and the edge region of the piezoelectric wafer is no greater than 10%.

In some embodiments, a difference in light transmittance of a first spectrum between the central region and the edge region of the piezoelectric wafer is no greater than 5%, where the first spectrum has a wavelength that ranges from 265 nm to 365 nm. Referring to FIGS. 11 and 12, the light transmittance of the central region is expressed by the solid line and that of the edge region is expressed by the dotted line. It is observable that the difference in light transmittance between the central region and the edge region of the exemplary sample is less than 5%.

In some embodiments, the piezoelectric wafer may have a difference in light transmittance of the first spectrum between the central region and the edge region that is no greater than 2%.

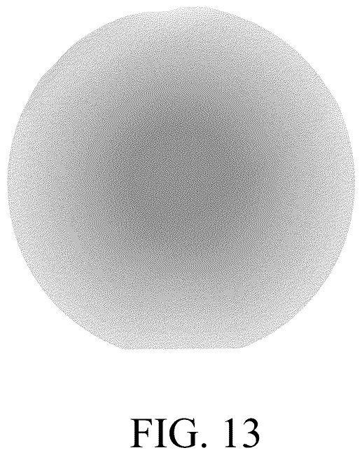

In some embodiments, the piezoelectric wafer made by the first embodiment has a resistivity difference that is less than 9×10¹⁰Ω. In this case, resistivity values are measured at several evenly distributed points selected from the central region and the edge region, and the difference between a maximum measured resistivity and a minimum measured resistivity is used as the resistivity difference. FIG. 13 shows a piezoelectric wafer with a resistivity difference that is no greater than 9×10¹⁰Ω.

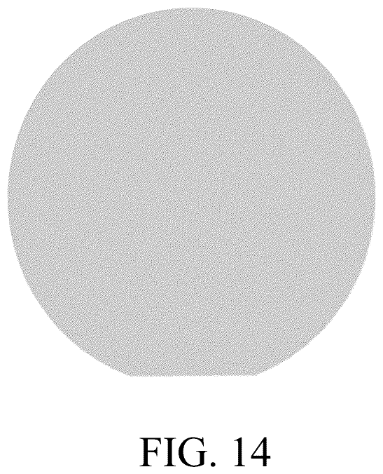

In some embodiments, the piezoelectric wafer has a resistivity difference that is less than 2×10¹⁰Ω. FIG. 14 shows a piezoelectric wafer with a resistivity difference that is no greater than 2×10¹⁰Ω. In other embodiments, the piezoelectric wafer has a resistivity difference that is less than 1×10¹⁴Ω.

According to the disclosure, there is provided an acoustic wave device which implements the piezoelectric wafer made by the first or second embodiment of the present disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A piezoelectric wafer comprising a center region and an edge region, wherein said piezoelectric wafer has a color difference (ΔE) of no greater than 3;
wherein the color difference (ΔE) is expressed by
$$Δ E = \sqrt{{( {L}_{max} - {L}_{mix} )}^{2}}$$
where the color difference (ΔE) is obtained from multiple chromaticity values (L) measured at several evenly distributed points selected from the central region and the edge region of the piezoelectric wafer, (Lₘₐₓ) is a maximum value of the chromaticity values (L), and (Lₘᵢₙ) is a minimum value of the chromaticity values (L).

2. The piezoelectric wafer as claimed in claim 1, wherein a difference in light transmittance of a first spectrum between said central region and said edge region of said piezoelectric wafer is no greater than 10%, where said first spectrum has a wavelength that ranges from 265 nm to 365 nm.

3. The piezoelectric wafer as claimed in claim 1, wherein a difference in light transmittance of a first spectrum between said central region and said edge region of said piezoelectric wafer is no greater than 5%, where said first spectrum has a wavelength that ranges from 265 nm to 365 nm.

4. The piezoelectric wafer as claimed in claim 1, wherein said color difference (ΔE) of said piezoelectric wafer is no greater than 1.

5. The piezoelectric wafer as claimed in claim 1, wherein said piezoelectric wafer has a resistivity difference that is less than 9×10¹⁰Ω.

6. The piezoelectric wafer as claimed in claim 1, wherein said piezoelectric wafer has a resistivity difference that is less than 2×10¹⁰Ω.

7. The piezoelectric wafer as claimed in claim 1, wherein said piezoelectric wafer is made of lithium tantalate or lithium niobate.

8. The piezoelectric wafer as claimed in claim 1, wherein said piezoelectric wafer has oxygen vacancies that are evenly distributed.

9. The piezoelectric wafer as claimed in claim 1, wherein said piezoelectric wafer has a resistivity difference that is less than 1×10¹⁴Ω.

10. The piezoelectric wafer as claimed in claim 1, wherein said piezoelectric wafer has a light transmittance in a first spectrum that is no greater than 20%, where said first spectrum has a wavelength that ranges from 265 nm to 365 nm.

11. A method of fabricating a piezoelectric wafer as claimed in claim 1, comprising processing a piezoelectric wafer so that a color difference (ΔE) of the piezoelectric wafer is no greater than 3;
wherein the color difference (ΔE) is expressed by
$$Δ E = \sqrt{{( {L}_{max} - {L}_{mix} )}^{2}}$$
where the color difference (ΔE) is obtained from multiple chromaticity values (L) measured at several evenly distribution areas selected from a central region and an edge region of the piezoelectric wafer, (Lₘₐₓ) is a maximum value of the chromaticity values (L), and (Lₘᵢₙ) is a minimum value of the chromaticity values (L).

12. The method as claimed in claim 11, wherein the processing of the piezoelectric wafer comprises:
slicing a piezoelectric crystal to obtain a piezoelectric wafer;
performing a first reduction treatment on the piezoelectric wafer;
oxidizing the piezoelectric wafer after the first reduction treatment; and
performing a second reduction treatment on the piezoelectric wafer after the oxidizing of the piezoelectric wafer.

13. The method as claimed in claim 11, wherein a reducing agent for performing the first reduction treatment on the piezoelectric wafer is a carbonate.

14. The method as claimed in claim 13, wherein said reducing agent is a carbonate powder with a fineness that ranges from 25 μm to 45 μm.

15. The method as claimed in claim 11, further comprising exposing the piezoelectric wafer to UV light rays after the second reduction treatment is performed.

16. An acoustic wave device comprising said piezoelectric wafer as claimed in claim 1.

17. The acoustic wave device as claimed in claim 16, wherein a difference in light transmittance of a first spectrum between said central region and said edge region of said piezoelectric wafer is no greater than 2%, where said first spectrum has a wavelength that ranges from 265 nm to 365 nm.

18. The acoustic wave device as claimed in claim 16, wherein said reducing agent is a carbonate powder with a fineness that ranges from 30 μm to 45 μm.

19. The acoustic wave device as claimed in claim 16, wherein said reducing agent is one of lithium carbonate, sodium carbonate, and magnesium carbonate, or a combination or combinations of the above.

20. The acoustic wave device as claimed in claim 16, wherein said color difference (ΔE) of said piezoelectric wafer is no greater than 1.
